(19) United States
(12) Patent Application Publication
(10) Pub. No.: US 2026/0059831 A1
(43) Pub. Date: Feb. 26, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Yu KAO, Hsinchu (TW); Shao-Hua HSU, Taitung (TW); Shih-Yao LIN, New Taipei (TW); Chun-Yu LIN, Yilan (TW); Yung-Chi CHANG, Hsinchu (TW)

(21) Appl. No.: 18/811,250

(22) Filed: Aug. 21, 2024

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/021; H10D 30/014; H10D 30/43; H10D 30/6735; H10D 30/6757; H10D 62/115; H10D 62/121; H10D 62/151; H10D 64/017; H10D 64/018; H10D 84/013; H10D 84/0135; H10D 84/0151; H10D 84/038; H10D 84/83

(57) ABSTRACT

Embodiments of the present disclosure provide a method to form a semiconductor device with low-k gate sidewall spacers without affecting DC performance. In some embodiments, the low-k gate sidewall spacers may be formed by depositing a gate sidewall spacer stack with one or more exterior layer(s) of higher k values and one or more interior layer(s) with lower k values. The exterior layer(s) with higher k values may be substantially removed during fabrication while the interior layer(s) with lower k value remain in the semiconductor device. In some embodiments, sacrificial gate electrode layer may include corner portions on top of the fin structures. The corner portions in the sacrificial gate electrode layer increases contact areas between gate structure and a top surface of the topmost channel layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for fabricating a semiconductor substrate according to embodiments of the present disclosure.

FIGS. 2-5, 6A-6B, 7A-7D, 8A-8C, 9A-9C, 10A-10B, 11A-11C, 12, 13A-13B, and 14A-14F schematically demonstrates various stages of manufacturing a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. Source/drain region(s) may refer to a source or a drain, individually or collectively dependent upon the context. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Gate sidewall spacer is an insulating layer in transistors. Using dielectric material with low k value improves AC performance in transistors. However, lower k material in the gate sidewall spacer is more difficult to etch than dielectric material of higher k value, resulting in reduced contact arear between gate and channel regions, which causes increased resistance and negatively affect DC performance. Embodiments of the present disclosure provide a method to form a semiconductor device with low-k gate sidewall spacers without affecting DC performance. In some embodiments, the low-k gate sidewall spacers may be formed by depositing a gate sidewall spacer stack with one or more exterior layer(s) of higher k values and one or more interior layer(s) with lower k values. The exterior layer(s) with higher k values may be substantially removed during fabrication while the interior layer(s) with lower k value remain in the semiconductor device. In some embodiments, sacrificial gate electrode layer may include corner portions on top of the fin structures. The corner portions in the sacrificial gate electrode layer increases contact areas between gate structure and a top surface of the topmost channel layer.

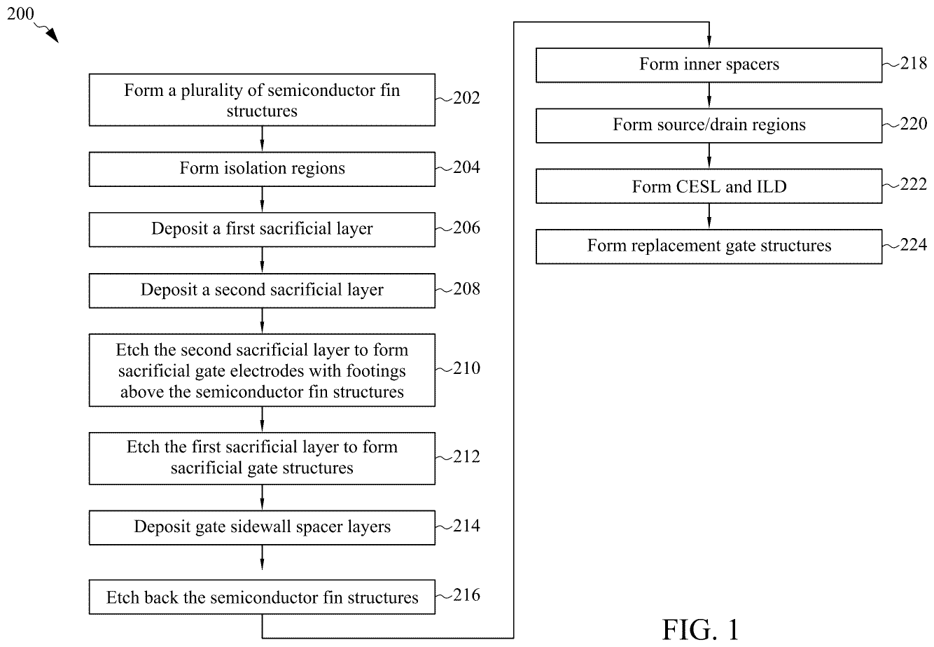

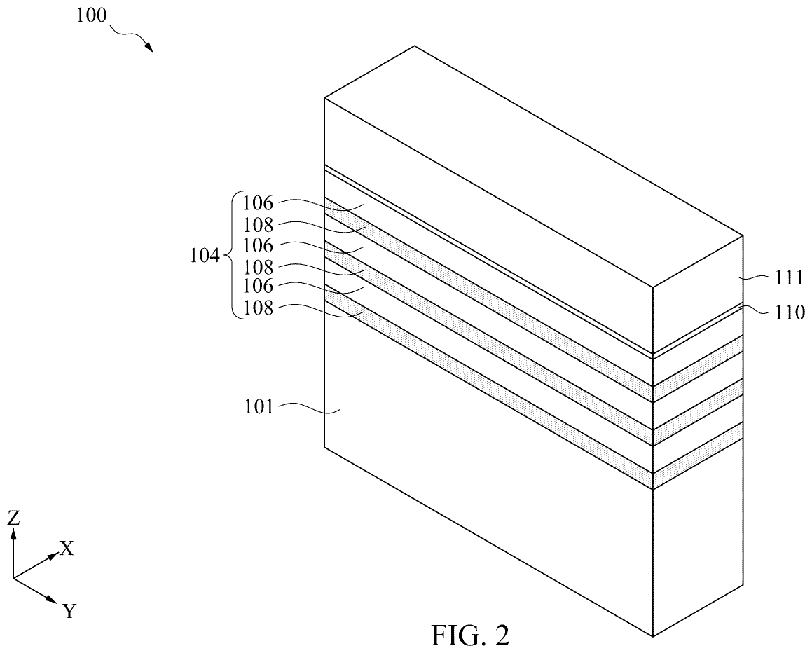

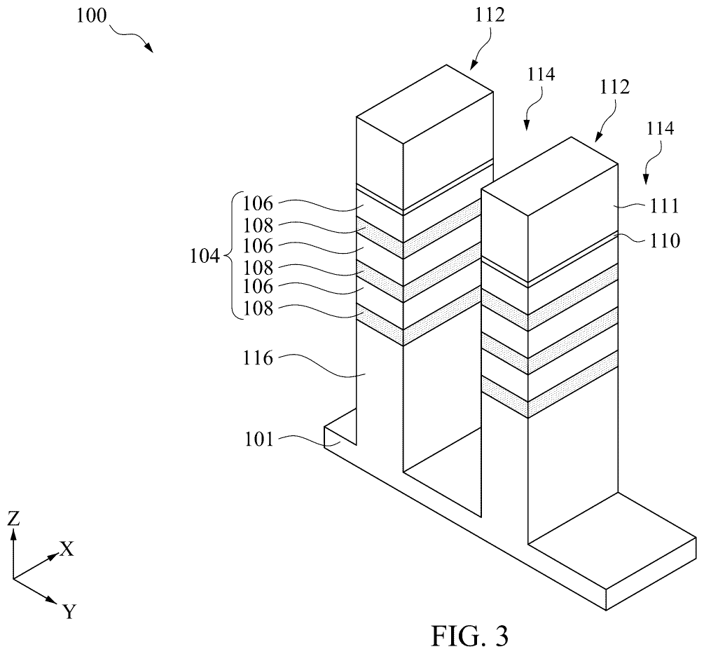

FIG. 1 is a flow chart of a method 200 for fabricating a semiconductor substrate according to embodiments of the present disclosure. FIGS. 2-5, 6A-6B, 7A-7D, 8A-8C, 9A-9C, 10A-10B, 11A-11C, 12, 13A-13B, and 14A-14F schematically demonstrates various stages of manufacturing a semiconductor device structure 100 in accordance with some embodiments. In some embodiments, the semiconductor device structure 100 may be fabricated using the method 200. It is understood that additional operations can be provided before, during, and after processes shown by FIG. 1 and FIGS. 2-14, and some of the operations described below can be replaced or eliminated, for additional embodiments of the method. The order of the operations/processes is not limiting and may be interchangeable.

In operation 202 of the method 200, a plurality of semiconductor fins 112 are formed, as shown in FIGS. 1 and 2. FIGS. 1-2 are perspective views of the semiconductor device structure 100. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

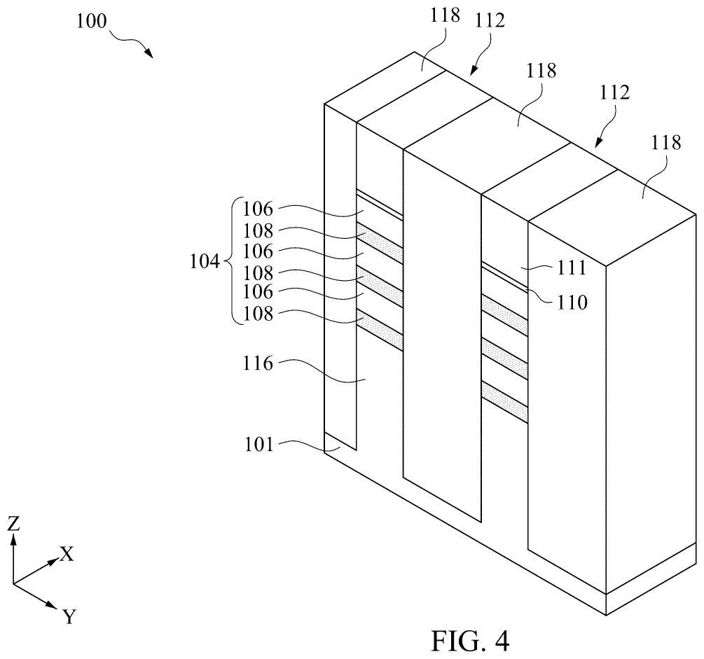

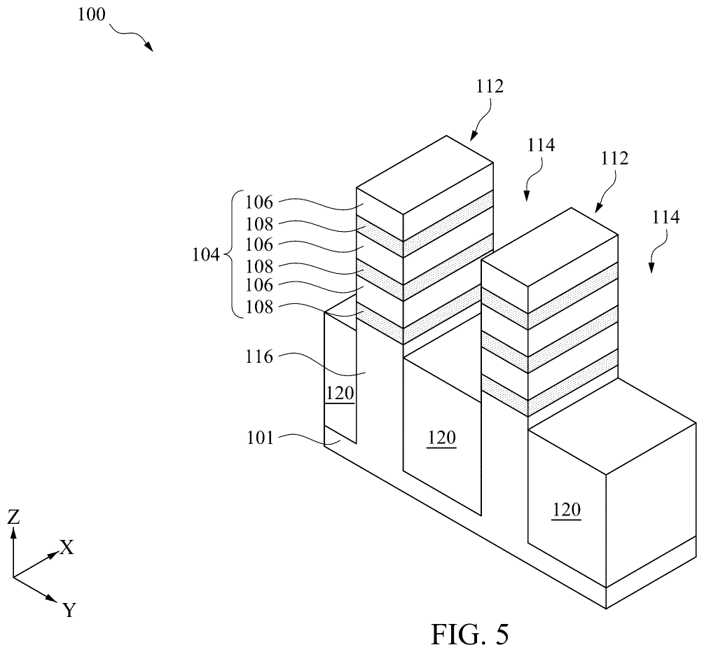

In operation 204, isolation regions 120 are formed around the semiconductor fin structures 112, as shown in FIGS. 4-5, which are perspective views of the semiconductor device structure 100. In FIG. 4, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

In FIG. 5, the insulating material 118 is recessed to form the isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the STI. In some embodiments, the oxide layer 110 and the nitride layer 111 are also removed during the recessing of the insulating material 118.

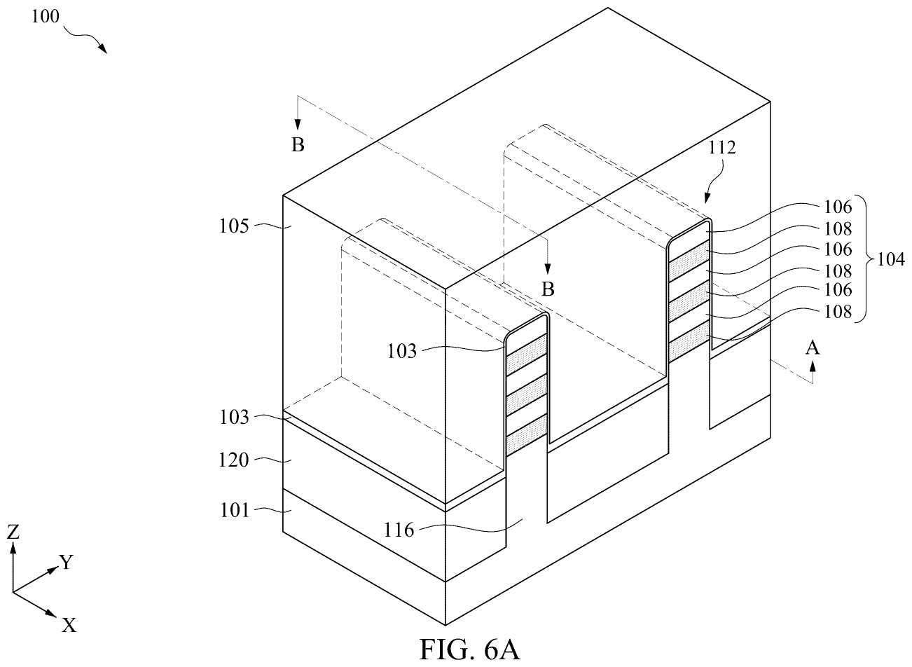

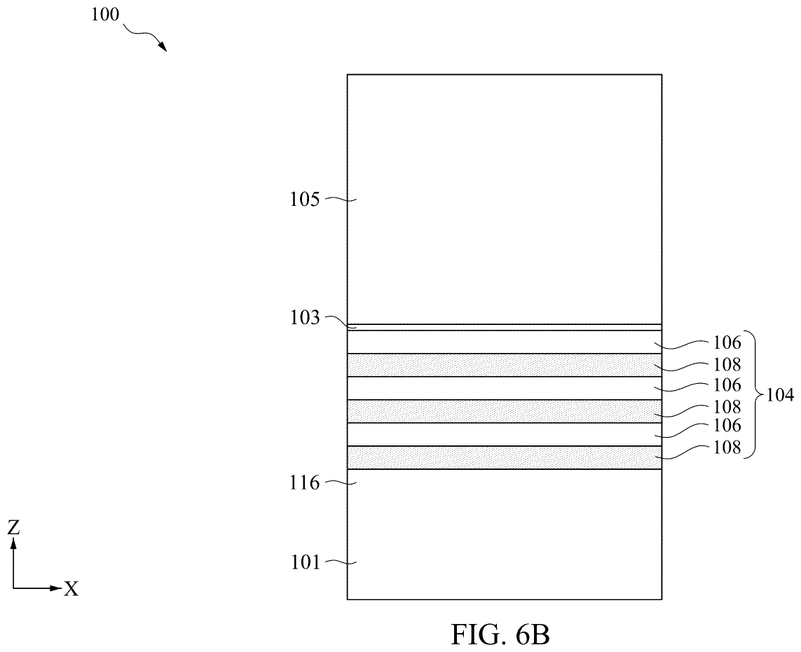

In operation 206, a sacrificial layer 103 is formed on the exposed surfaces of the semiconductor device structure 100, as shown in FIGS. 6A and 6B. FIG. 6A is a schematic perspective view of the semiconductor device structure 100. FIG. 6B is a schematic cross-sectional view of the semiconductor device structure 100 along lines B-B in FIG. 6A. FIG. 6B, a cross-sectional view along one of the fin structures 112, is also referred to as x-cut. In some embodiments, the first sacrificial layer 103 includes a dielectric material, such as an oxide, for example silicon oxide. The first sacrificial layer 103 may be formed by any suitable process, such as CVD or PECVD. In some embodiments, the first sacrificial layer 103 is a conformal layer formed by a conformal process, such as atomic layer deposition (ALD).

In operation 208, a second sacrificial layer 105 is deposited over the first sacrificial layer 103, as shown in FIGS. 6A-6B. In some embodiments, the second sacrificial layer 105 includes a semiconductor material, such as polysilicon. The second sacrificial layer 105 may be formed by any suitable process, such as CVD, PECVD, ALD, or PVD. The second sacrificial layer 105 may be first deposited to embed the fin structures 112, followed by a planarization process, such as a CMP process. In some embodiments, the second sacrificial layer 105 may have a thickness in the Z direction ranging from about 100 nm to about 200 nm.

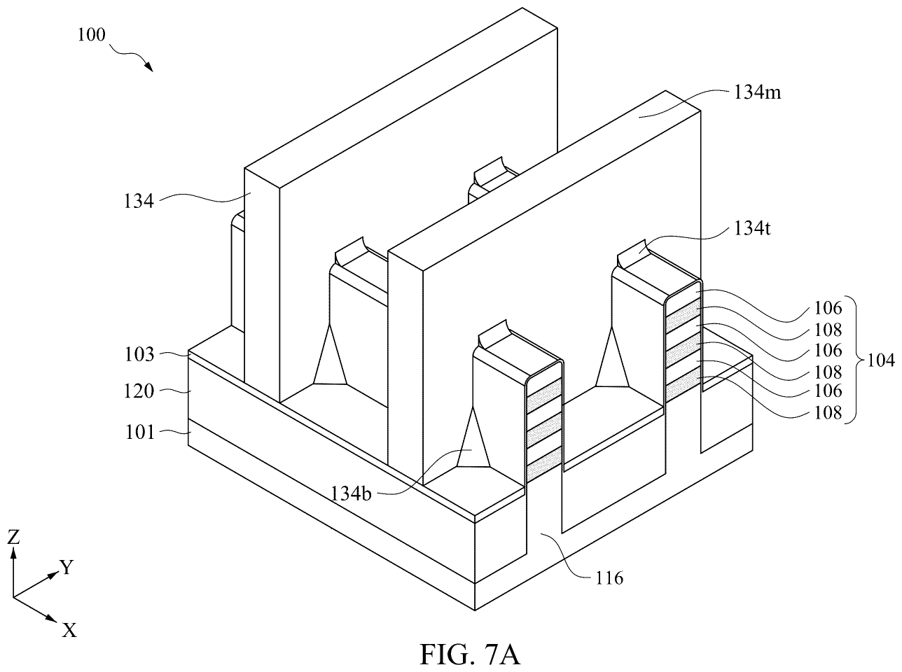

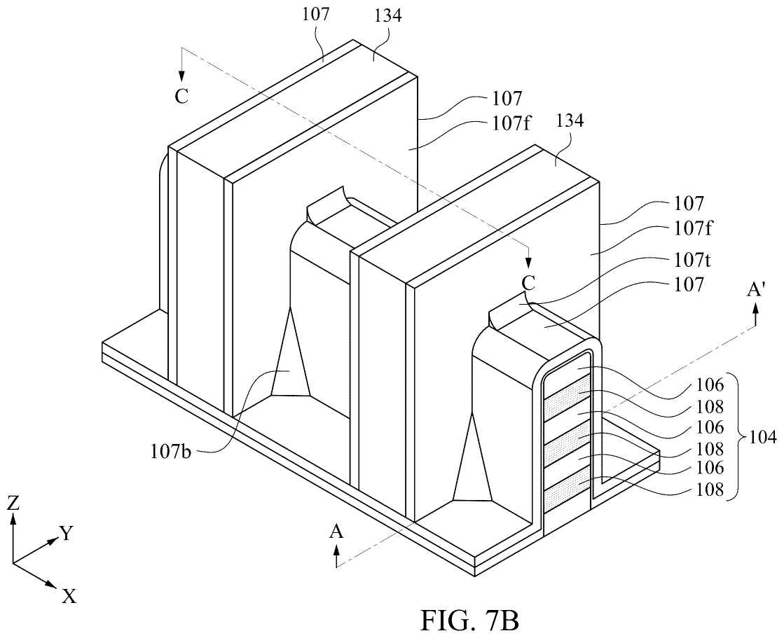

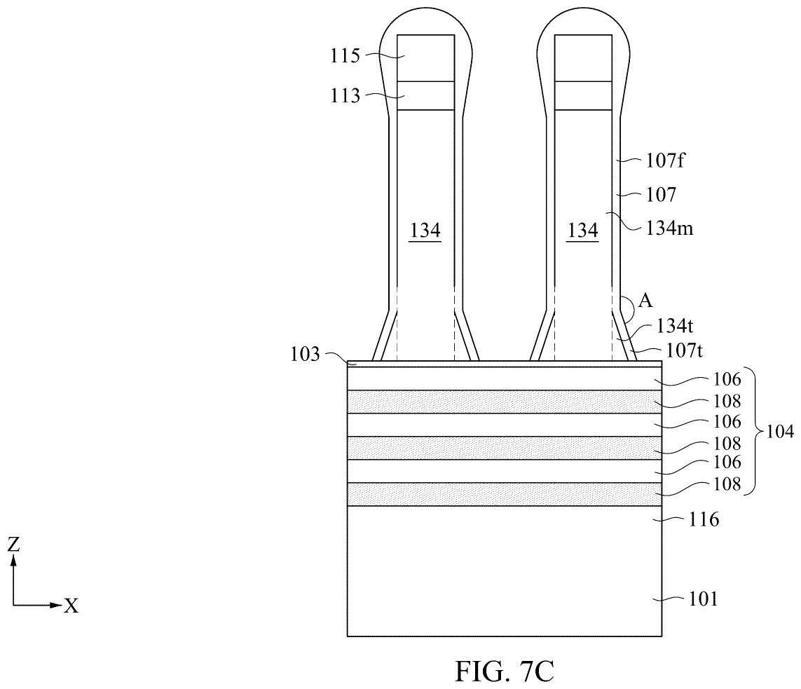

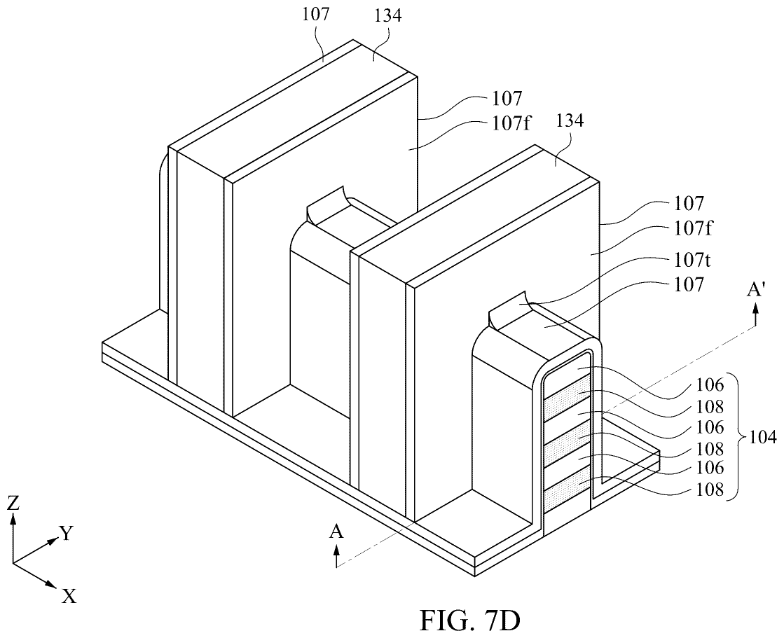

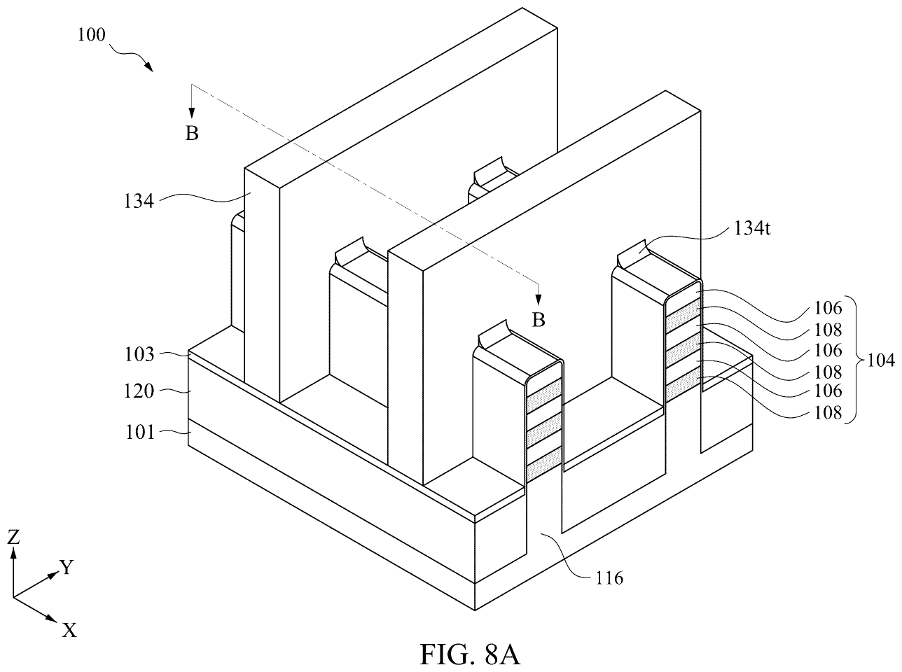

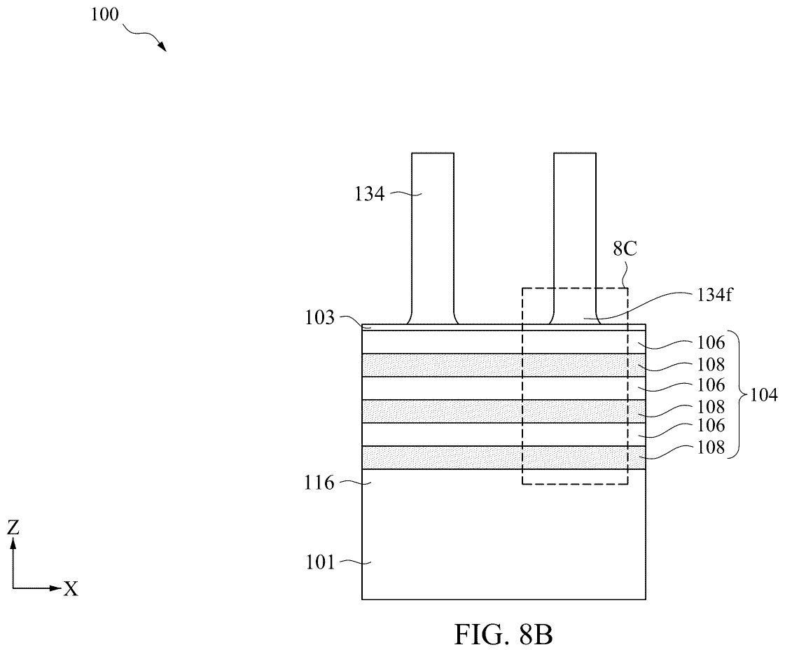

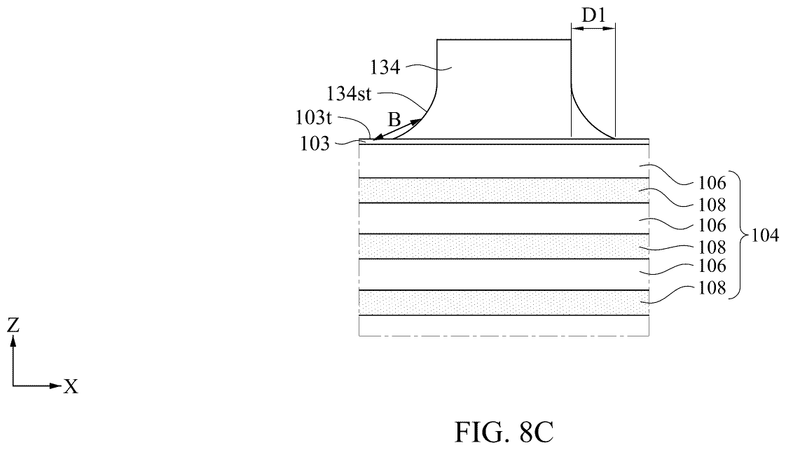

In operation 210, sacrificial gate electrode layers 134 with footings 134f over a top surface 112f of the fin structures 112 are formed, as shown in FIGS. 7A-7D and FIGS. 8A-8C. The sacrificial gate electrodes 134 are formed by etching the second sacrificial layer 105 using one or more etching processes.

FIG. 7A is a schematic perspective view of the semiconductor device structure 100 after a main etch process. FIG. 7B is a schematic perspective view of the semiconductor device structure 100 showing a by-product layer 107 after the main etch process. FIG. 7C is a schematic cross sectional view of the semiconductor device structure 100 along the C-C line in FIG. 7B. FIG. 7D is a schematic perspective view of the semiconductor device structure 100 after the soft landing etch process.

FIG. 8A is a schematic perspective view of the semiconductor device structure 100 after an over etch process. FIG. 8B is a schematic cross sectional view of the semiconductor device structure 100 along the B-B line in FIG. 8A. FIG. 8C is a partial enlarged view of FIG. 8B showing details of the footing 134f.

In some embodiments, a mask layer may be formed on the second sacrificial layer 105 after the planarization process. The mask layer may include more than one layer, such as an oxide layer 115 and a nitride layer 113, shown in FIG. 7C. The mask layer is omitted in FIGS. 7A, 7B, 7D, and 8A to 8C for clarity. As shown in FIG. 7C, the mask layer is used to pattern the second sacrificial layer 105 to form one or more sacrificial gate electrode layer 134. The patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof.

After patterning the mask layer, an etch process according to the present disclosure may be performed to form the sacrificial gate electrode layer 134 from the second sacrificial layer 105. The etch process that may include dry etching (e.g., RIE etching), wet etching, other etching methods, and/or combinations thereof. In some embodiments, the sacrificial gate electrode layers 134 may be formed by performing multiple etch processes, such as a main etch process, a breakthrough process, a soft landing etching process, a passivation process, and an over etching process.

In some embodiments, the main etching process includes an anisotropic dry etching process using a chlorine-based etchant. In some embodiments, the main etching process may be a plasma etch process and may utilize etchants and other gases such as Cl2, HBr, CH2F2, CHF3, CH3F, O2, and/or Ar. The process pressure of the main etching process may range from about 40 mT to about 800 mT, and the plasma power of the main etching process may range from about 200 W to about 1500 W. In some embodiments, other etchants, such as HBr and/or oxygen-containing etchant, may be used. Carrier or dilute gas, such as Ar, N2, or He, may be also used in addition to the etchants in the anisotropic dry etching process.

During the anisotropic dry etching process, byproducts, such as SiO, SiO—Cl, SiO—HBr, SiO—N, or SiO—Ar, may be formed on the surfaces of the semiconductor device structure 100. As a result, a byproduct layer 107 is formed on the surfaces of the semiconductor device structure 100, such as around the sacrificial gate electrode layer 134, the nitride layer 113, the oxide layer 115, and on the first sacrificial layer 103, as shown in FIGS. 7B and 7C. In some embodiments, the second sacrificial layer 105 has a thickness ranging from about 200 nm to about 300 nm. Portions, such as first corner portions 134t and second corner portions 134b of the second sacrificial layer 105 located at corners may not be removed by the anisotropic dry etching process. As shown in FIG. 7A, the first corner portions 134t are located between the side surface of the sacrificial gate electrode layer 134 and the portion of the first sacrificial layer 103 located on the topmost first semiconductor layer 106. The second corner portions 134b are between the side surface of the sacrificial gate electrode layer 134 and the portion of the first sacrificial layer 103 located on side surfaces of the bottommost first and second semiconductor layers 106, 108.

In addition, the byproduct layer 107 may be formed on the first and second corner portions 134t, 134b of the second sacrificial layer 105 located at corners, which makes the anisotropic etching process even harder to remove the portions of the second sacrificial layer 105, because the etchant used in the anisotropic etching process is for etching semiconductor materials, such as polysilicon. As described above, the byproduct layer 107 is a silicon oxide-based material. Furthermore, a subsequent process to remove the byproduct layer 107 may use an etchant that removes oxide.

As shown in FIGS. 7B and 7C, the byproduct layer 107 includes a first corner portion 107t located between the side surface of the sacrificial gate electrode layer 134 and the portion of the first sacrificial layer 103 located on the topmost first semiconductor layer 106. The byproduct layer 107 includes a substantially flat portion 107f, and the first corner portion 107t extends from the substantially flat portion 107f. In some embodiments, an angle A is formed between the substantially flat portion 107f and the first corner portion 107t of the byproduct layer 107, and the angle A is less than 180 degrees. In some embodiments, the angle A ranges from about 120 degrees to about 170 degrees. The first corner portion 107t may be located on both sides of the sacrificial gate electrode layer 134, as shown in FIG. 7C. The sacrificial gate electrode layer 134 includes a main portion 134m and the first corner portion 134t extends from the main portion 134m on both sides of the sacrificial gate electrode layer 134. An outer surface of the main portion 134m and an outer surface of the first corner portion 134t may form an angle, and the angle may be the same as the angle A. In some embodiments, the sacrificial gate electrode layer 134 includes a top portion having substantially constant width along the X direction and a bottom portion having increasing width in a direction towards the substrate 101.

Referring to FIG. 7C, the byproduct layer 107 further includes second corner portions 107b located between the side surface of the sacrificial gate electrode layer 134 and the portion of the first sacrificial layer 103 located on side surfaces of the bottommost first and second semiconductor layers 106, 108 not covered by the sacrificial gate electrode layer 134. The second corner portion 107b extends from the substantially flat portion 107f and is in contact with the portion of the byproduct layer 107 located adjacent the portion of the stack of semiconductor layers 104 not covered by the sacrificial gate electrode layer 134. The second corner portion 107b of the byproduct layer is formed on the second corner portion 134b of the sacrificial gate electrode layer 134. The second corner portion 134b of the sacrificial gate electrode layer 134 may have similar shape as the second corner portion 107b.

The breakthrough process may be performed after the main etching process. In some embodiments, the breakthrough process may be an anisotropic dry etching process that uses an etchant to remove the first and second corner portions 107f, 107b of the byproduct layer 107. In some embodiments, the breakthrough process is a plasma etch process and may utilize etchants and other gases such as CF4, C4F6, CHClF2, and/or Ar. The process pressure of the breakthrough process may range from about 1 mT to about 100 mT, and the plasma power of the breakthrough process may range from about 50 W to about 1000 W.

In some embodiments, the breakthrough process may use an etchant including HF, NH3, or a combination thereof. The etchant removes oxide-based material at a much faster rate than semiconductor materials. Furthermore, the anisotropic dry etching process is controlled to remove the second corner portions 107b of the byproduct layer 107, and the main portion 107m and the first corner portion 107t of the byproduct layer 107 are not substantially affected.

The soft landing etching process may be a plasma etch process and may utilize etchants and gases such as Cl2, HBr, CH2F2, CF4, C4F6, CHClF2, HF, O2, and/or Ar. In some embodiments, the soft landing etching process has a plasma power ranging from about 100 W to about 500 W. The plasma power may be generated by a first radio frequency (RF) power source, and the plasma power may be pulsed. In some embodiments, the soft landing etching process has a bias power ranging from about 600 W to about 1200 W. The bias power may be generated by a second RF power source that is different from the first RF power source. The plasma power and the bias power may be pulsed.

The passivation process may be performed after the soft landing etching process. The passivation process protects the vertical surfaces of the second sacrificial layer 105. The passivation process may be performed using a passivation gas for etch selectivity. In some embodiments, the passivation gas may include N2, O2, CO2, or the like. In some embodiments, dilute gas, such as He, Ar, or N2 may be used. In some embodiments, the passivation process is a plasma treatment process using a nitrogen-containing plasma. The plasma power of the passivation process may range from about 500 W to about 1000 W. The process pressure of the passivation process may range from about 50 mT to about 100 mT. In some embodiments, has a duty cycle ranging from about 3 percent to about 20 percent The over etch process may be a plasma etch process and may utilize etchants and gases such as CHF₃, CF₄, CH₂F₂, HF, NH₃. In some embodiments, the etching process may further include a passivation gas, such as N2, O₂, or CO₂, for selectivity and dilute gas such as He, Ar, or N_{2.} The flow rates of the various gases of the over etching process may range from about 20 sccm to about 3000 sccm. The plasma power of the second etching process may range from about 10 W to about 4000 W, and the processing pressure may range from about 1 mTorr to about 800 mTorr.

The over etch process may remove exposed portions of sacrificial gate electrode layer 134. In some embodiments, the second corner portions 134b are substantially removed while the first corner portions 134t remains, as shown in FIGS. 8A-8C. The dimension D1 in the Y direction and the dimension in the X direction of the remaining first corner portion 134t may be in a range between about 1.5 nm to about 3.0 nm. In some embodiments, an angle B is formed between a top surface 103s of the first sacrificial layer 103 and a sidewall 134ts of the first corner portion 134t of the sacrificial gate electrode layer 134. In some embodiments, the angle B is an obtuse angle. In some embodiments, the angle B is in a range from about 96 degrees to about 110 degrees. The first corner portions 134t increases the footing of the sacrificial gate electrode layer 134 and increase contact area between gate electrode and channel regions.

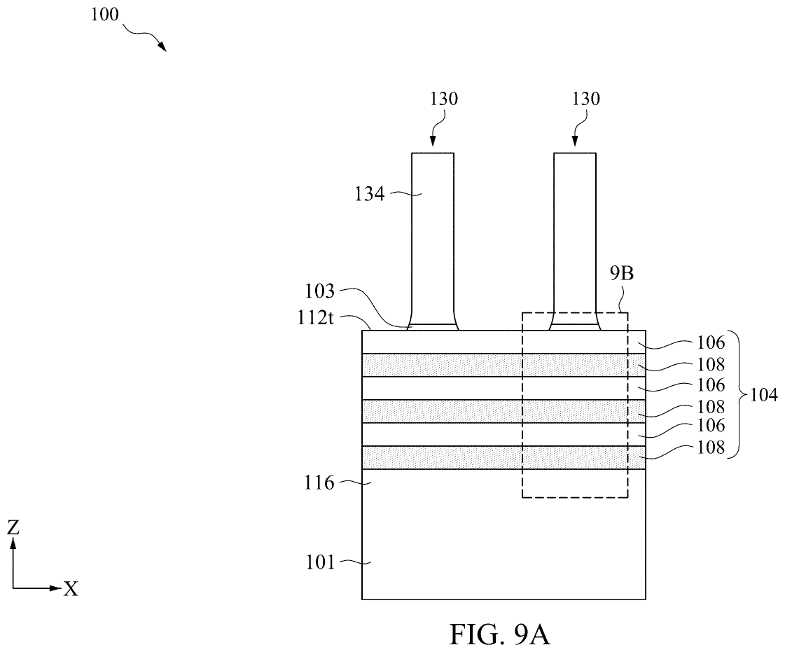

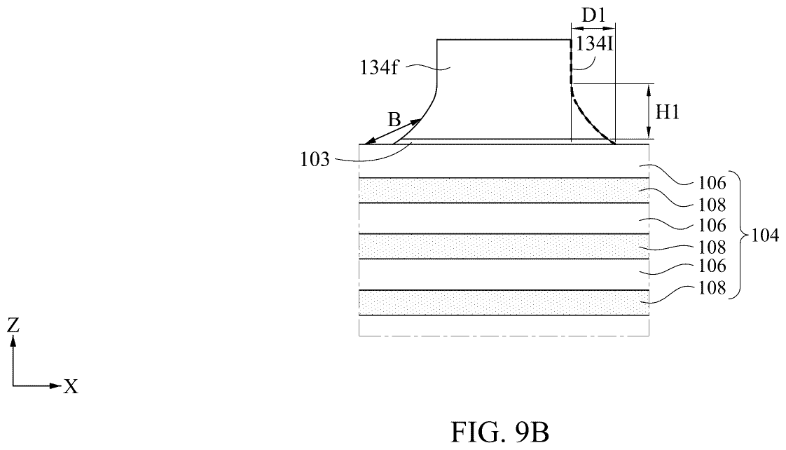

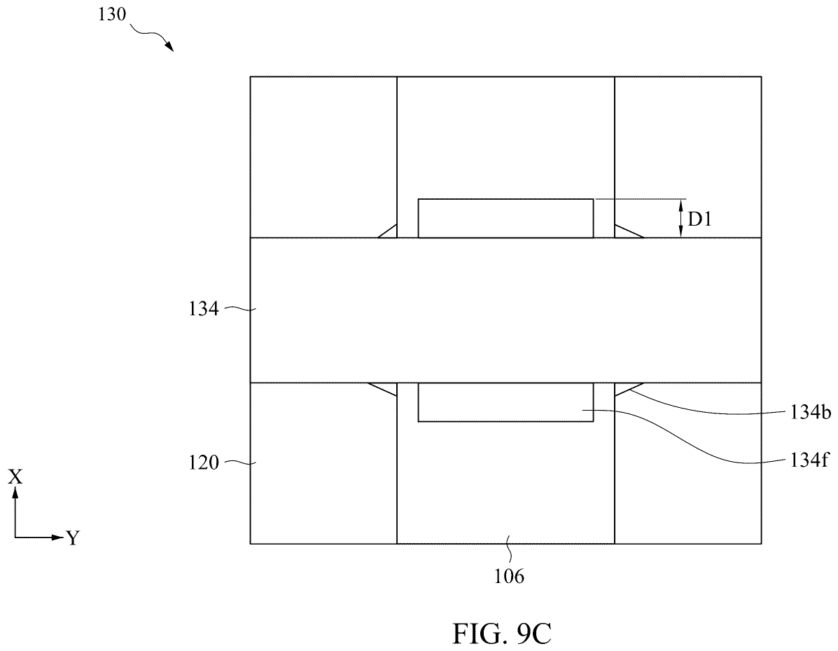

In operation 212, exposed portion of the first sacrificial layer 103 is removed to form sacrificial gate structures 130, as shown in FIGS. 9A-9C. FIG. 9A is a schematic cross sectional view of the semiconductor device structure 100 along the B-B line in FIG. 8A. FIG. 9B is a partial enlarged view of FIG. 9A showing details of the footing portion. FIG. 9C is a schematic partial top view of the semiconductor device structure 100. In some embodiments, an etching process is performed to remove the exposed portions of the first sacrificial layer 103. After the removal of the byproduct layer 107 and the exposed portions of the first sacrificial layer 103, the sacrificial gate electrode layer 134, the portion of the first sacrificial layer 103 disposed under the sacrificial gate electrode layer 134, and the mask layer (the nitride layer 113 and the oxide layer 115 shown in FIG. 7C) form a sacrificial gate structure 130.

As shown in FIGS. 9B and 9C, the sacrificial gate structures 130 include the corner portions 134t over the top surface 112t of the fin structures 112. The corner portions 134t provide footing for the sacrificial gate structures 130 and enable substantially vertical sidewalls in the replacement gate structures as described later.

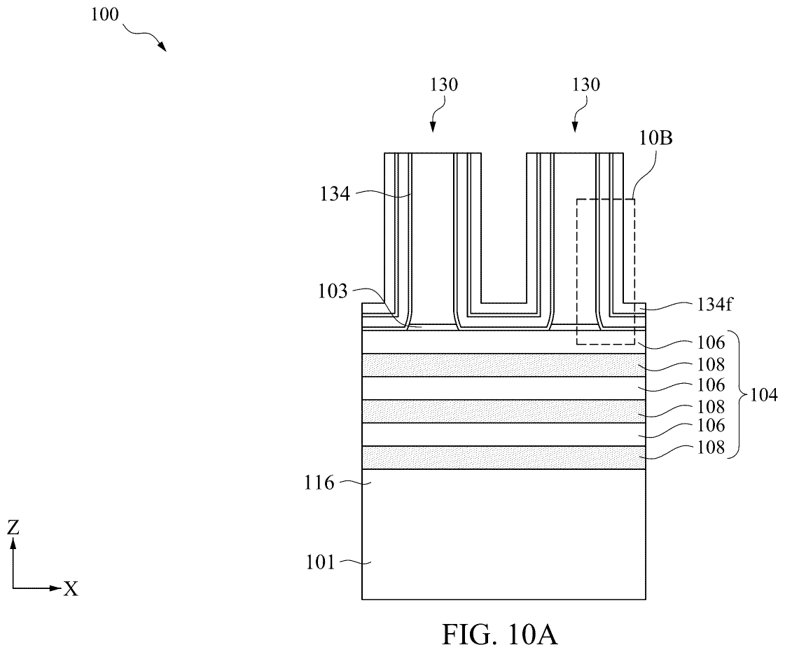

In operation 214, a gate sidewall spacer stack 138 deposited on exposed surfaces of the semiconductor device structure 100, as shown in FIGS. 10A and 10B. FIG. 10A is a schematic cross sectional view of the semiconductor device structure 100. FIG. 10B is a partial enlarged view of the semiconductor device structure 100 in area 10B of FIG. 10A. In some embodiments, the gate sidewall spacer stack 138 may include two or more dielectric layers of different dielectric values. The two or more dielectric layers may be sequentially deposited by blanket deposition. In some embodiments, the gate sidewall spacer stack 138 may include a bottom layer, one or more interior layers, and a top layer, wherein the bottom layer and top layer have higher dielectric value than the one or more interior layers. During subsequent fabrication, the top layer and the bottom layer may be substantially removed while the interior layers remain as the gate sidewall spacers in the resulting device. The higher k value in the bottom layer and the top layer allow sidewalls of the gate structures to remain substantially vertical and the lower k value of the interior layers enables improved performance.

As shown in FIGS. 10A and 10B, the gate sidewall spacer stack 138 includes a bottom layer 138A, a first interior layer 138B, a second interior layer 138C, and a top layer 138D. The layers 138A, 138B, 138C, 138D may be sequentially deposited on the sacrificial gate structures 130. In some embodiments, the layers 138A, 138B, 138C, 138D may be formed by conformal depositions sequentially. In some embodiments, the gate sidewall spacer stack 138 includes two or more layers of silicon and nitrogen containing layers with different k-values and thicknesses. In some embodiments, the k-values in the layers of the gate sidewall spacer stack 138 may be achieved by tuning compositions of the layers.

In some embodiments, the gate sidewall spacer stack 138 includes two or more dielectric layers comprising silicon, oxygen, carbon, and nitrogen. The dielectric layers in the gate sidewall spacer stack 138 are different in k-value and thickness. The k-values in the dielectric layers may be achieved by adjusting compositions of the layers. For example, increasing the ratio of nitrogen over silicon to increase the k-value, reducing the ratio of nitrogen over silicon to reduce the k-value, increasing the ratio of oxygen over silicon to reduce the k-value, reducing the ratio of oxygen over silicon to increase the k-value, increasing the ratio of carbon over silicon to increase the k-value, reducing the ratio of carbon over silicon to reduce the k-value, or a combination thereof. In some embodiments, the composition may be selected to according to achieve adhesion between layers, and/or to achieve desirable mechanical strength.

The bottom layer 138A is deposited directly on the exposed surfaces of the semiconductor device structure 100 after operation 212. Particularly, the bottom layer 138A is deposited on exposed surfaces of the sacrificial gate electrode 134, the fin structures 112, and the isolation region 120. In some embodiments, the bottom layer 138A is intended as a sacrificial layer with majority of the bottom layer 138A removed during subsequent fabrication. The bottom layer 138A may be formed from a dielectric material with good etch selectivity.

In some embodiments, the bottom layer 138A is a SiCON layer having a composition of Si:C:O: N in atomic ratio of 34:14:48:4. The relative high oxygen concentration in the bottom layer 138A allows the bottom layer 138A to adhere to the silicon containing semiconductor surfaces, such as the sacrificial gate electrode layer 134 and the semiconductor fins structures 112. In some embodiments, the bottom layer 138A has a thickness in a range between about 1.0 nm and 1.5 nm. The bottom layer 138A may have a k value in a range between about 4.4 and 4.8, for example about 4.6. In some embodiments, the bottom layer 138A may be a SiCON layer.

The first interior layer 138B is deposited on the bottom layer 138A. In some embodiments, the first interior layer 138B has a k value lower than the bottom layer 138A. The first interior layer 138B is intended to remain as gate sidewall spacers in the final device. In some embodiments, the first interior layer 138B may be selected from a dielectric material with a low k valve to achieve desirable performance. In some embodiments, the first interior layer 138B may be a SiCO layer. In some embodiments, the first interior layer 138B is a SiCO layer having a composition of Si:C:O in atomic ratio of 30:6:64. In some embodiments, the first interior layer 138B has a thickness in a range between about 1.0 nm and 1.5 nm. The first interior layer 138B may have a k value in a range between about 3.6 and 4.0, for example about 3.8.

The second interior layer 138C is deposited on the first interior layer 138B. In some embodiments, the second interior layer 138C is intended to remain as gate sidewall spacers in the final device, therefore, the second interior layer 138C may be selected from a dielectric material with a low k valve to achieve desirable performance. In some embodiments, the second interior layer 138C has a k value lower than the bottom layer 138A. The second interior layer 138C may have a k value higher than the first interior layer 138B. In some embodiments, the interior layer 138B may be a SiCO layer. In some embodiments, the interior layer 138B is a SiCO layer having a composition of Si:C:O in atomic ratio of 30:6:64. In some embodiments, the interior layer 138B has a thickness in a range between about 1.0 nm and 1.5 nm. The interior layer 138B may have a k value in a range between about 3.6 and 4.0, for example about 3.8.

The top layer 138D is deposited on the second interior layer 138C. In some embodiments, the top layer 138D is intended as a sacrificial layer to be removed during subsequent process. In some embodiment, the top layer 138D may be formed from a dielectric material with good etch selectivity. In some embodiments, the top layer 138D is a SiCON layer having a composition of Si:C:O:N in atomic ratio of 37:6:34:23. The relative high nitrogen concentration in the top layer 138D provides good etch selectivity. In some embodiments, the top layer 138D has a thickness in a range between about 4.0 nm and 6.0 nm. The top layer 138D may have a k value in a range between about 4.8 and 5.2, for example about 5.0.

As discussed above, the gate sidewall spacer stack 138 include exterior layers, such as the bottom layer 138A and the top layer 138D, as sacrificial layers, and one or more interior layers, such as the first interior layer 138B and the second interior layer 138C, as intended spacer layers. The interior layers may have low k values to improve device performance while the exterior layers are selected to achieve etch selectivity. The layers may be deposited sequentially in any suitable methods. In some embodiments, the layers in the gate sidewall spacer stack 138 maybe deposited in separate deposition processes.

In another embodiments, the layers of gate sidewall spacer stack 138 may be deposited by continuously in the same process chamber by adjusting composition of the processing gases. For example, the bottom layer 138A may be first deposited using processing gases containing a silicon source, a carbon source, an oxygen source, and a nitrogen source; when a desired thickness is achieved for the bottom layer 138A, the processing gases may be adjusted to form layers with lower k values. In some embodiments, flow rate of the nitrogen source and/or carbon source may be reduced to form a low k dielectric layer, such as the first interior layer 138B. In some embodiments, the flow rate of the nitrogen source may be ceased to deposit an interior layer, such as the first interior layer 138B. In some embodiments, flow rate of the oxygen ration source may be increased to deposit the first interior layer 138B with lower k value. When a desired thickness is achieved for the first interior layer 138B, the processing gases may be adjusted to form a second interior layer with a low k value. In some embodiments, flow rate of the nitrogen source may be increased while the flow rate of the carbon source may be increased to form a second interior layer with a low k value, such as the second interior layer 138C. When a desired thickness is achieved for the second interior 138C, the processing gases may be adjusted to form a top layer, such as the top layer 138D. In some embodiments, flow rate of the nitrogen source may be increased to form the top layer, such as the top layer 138D.

Even though four layers are shown in the gate sidewall spacer stack 138, more or less layers may be included. In some embodiments, three or more interior layers may be formed between the bottom layer and the top layer. In some embodiments, the top layer 138D may be omitted. In some embodiments, the bottom layer 138A may be omitted.

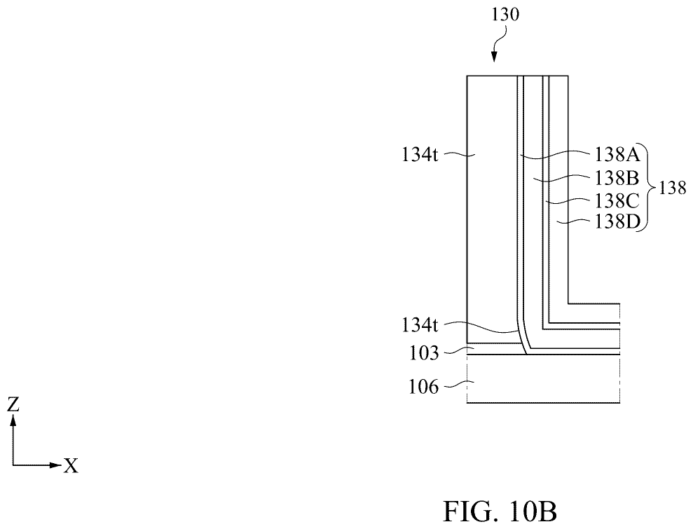

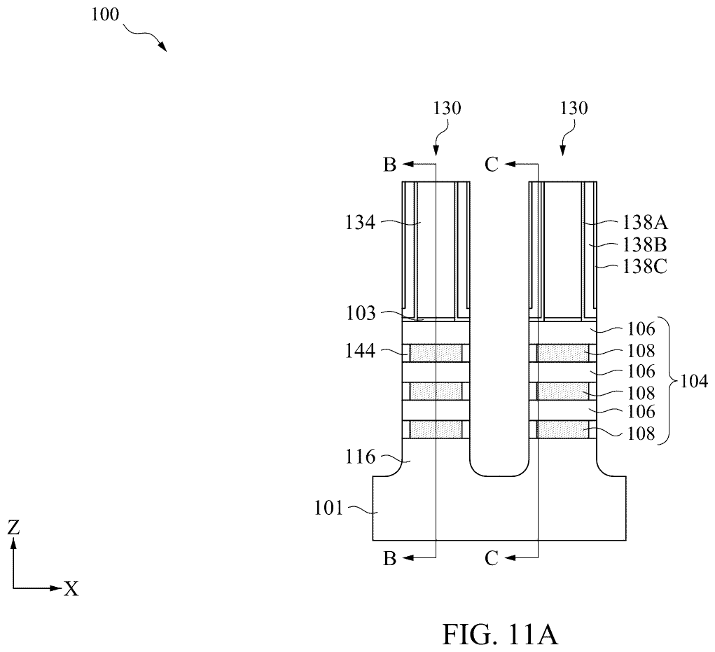

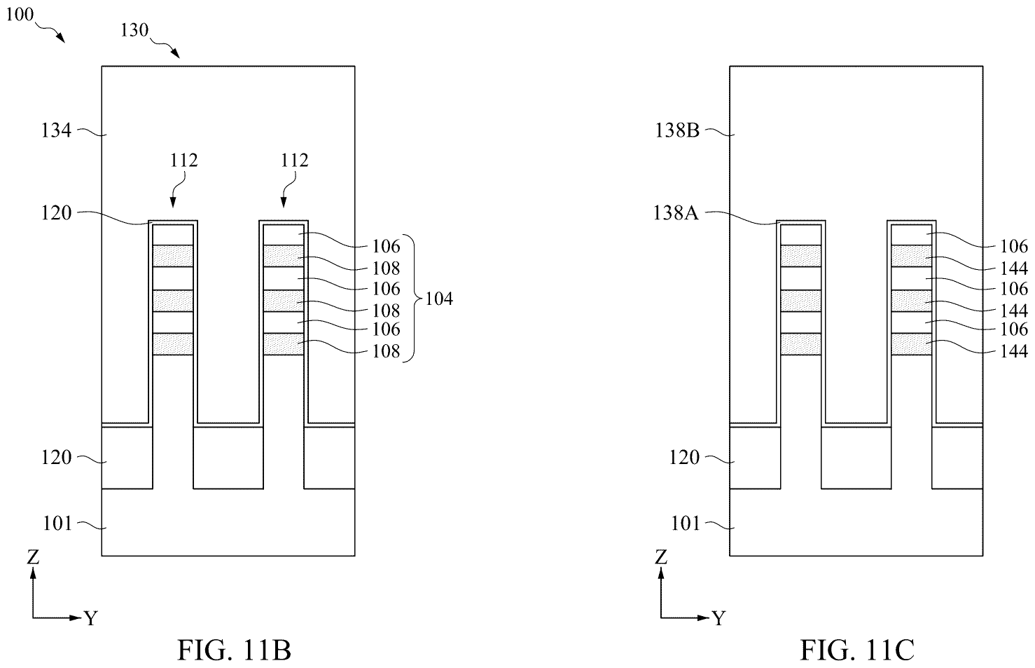

In operation 216, portions of the fin structures 112 not covered by the sacrificial gate structure 130 are recessed to a level above, at, or below the top surfaces of the isolation regions 120, as shown in FIGS. 11A-11C. FIG. 11A is a schematic cross sectional view of the semiconductor device structure 100 along the A-A line in FIG. 11B. FIGS. 11B and 11C are schematic cross sectional views of the semiconductor device structure 100 along the B-B line and C-C line in FIG. 11A respectively.

The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

In operation 218, inner spacers 144 are formed, as shown in FIGS. 11A-11C. Edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144, as shown in FIG. 11. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are shielded by the first semiconductor layers 106 during the anisotropic etching process. The remaining second semiconductor layers 108 are capped between the dielectric spacers 144 along the X direction.

As shown in FIG. 11A, the top layer 138D of the gate sidewall spacer stack 138 may be removed after fin structure etch back and inner spacer formation. Only the bottom layer 138A, the first interior layer 138B and the second interior layer 138C remain on the sidewalls of the sacrificial gate electrode 134. Cross sections of the bottom layer 138A and the first interior layer 138B are exposed to the cavities between the sections of the fin structures 112. As shown in FIGS. 11A and 11C, the bottom layer 138A wraps around the edge regions of the fin structure 112, while the first interior layer 138B and the second interior layer 138C are disposed over the bottom layer 138A over the sidewalls of the sacrificial electrode layer 134.

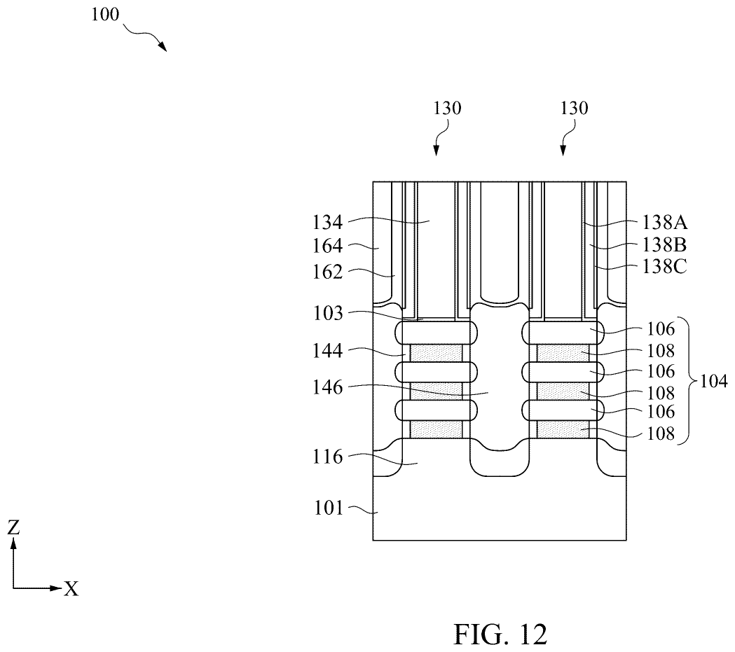

In operation 220, source/drain (S/D) regions 146 in the cavities between sections of the fin structures 112, as shown in FIG. 12. FIG. 12 is a cross sectional view of the semiconductor device structure 100. The S/D regions 146 may grow both vertically and horizontally from exposed semiconductor materials, such as the semiconductor layers 106 and the well portion 116, to form facets of crystalline materials. The facets may correspond to crystalline planes of the material used for the well portion 116 and the semiconductor layers 106. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. The S/D regions 146 may include one or more layers with different dopants.

As shown in FIG. 12, the S/D regions 146 may extend vertically pass the topmost semiconductor layer 106 and in contact with the gate sidewall spacer stack 138. The S/D regions 146 are in contact with cross sections of the bottom layer 138A and the first interior layer 138B of the gate sidewall spacer stack 138. The S/D regions 146 may also in contact with portions of the second interior layer 138C.

In operation 222, a contact etch stop layer (CESL) 162 and an interlayer dielectric (ILD) layer 164 are formed over the source/drain regions 146, as shown in FIG. 12. conformally formed on the exposed surfaces of the semiconductor device structure 100. The CESL 162 covers the sidewalls of the sacrificial gate structure 130 (the exposed portion of the gate sidewall spacer stack 138), the insulating material 120, and the S/D regions 146. As shown in FIG. 12, the CESL 162 is in contact with The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique.

As shown in FIG. 12, the CESL 162 covers exposed portions of the gate sidewall spacer stack 138. Particularly, the CESL 162 in contact with the second interior layer 138C. Depending on the volume and shape of the S/D regions 146, the CESL 162 may be in contact with cross sections the first interior layer 138B of the gate sidewall spacer stack 138.

The interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 12.

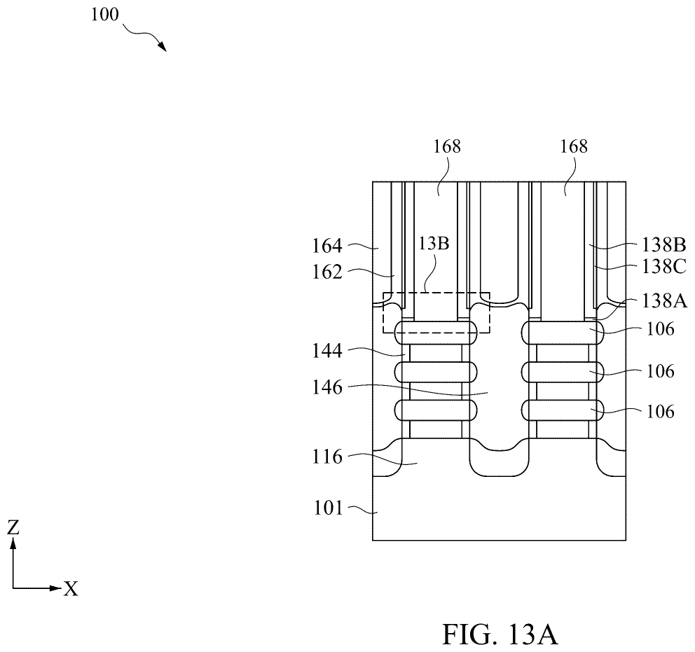

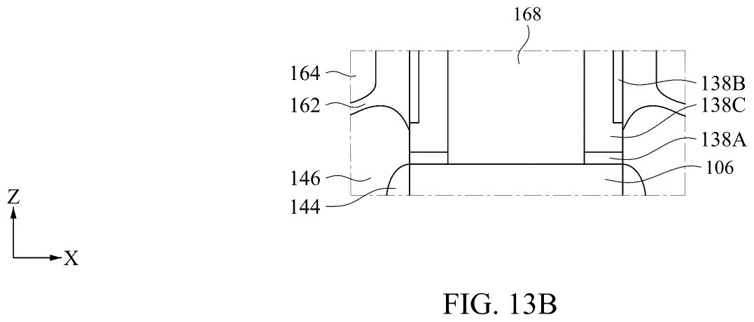

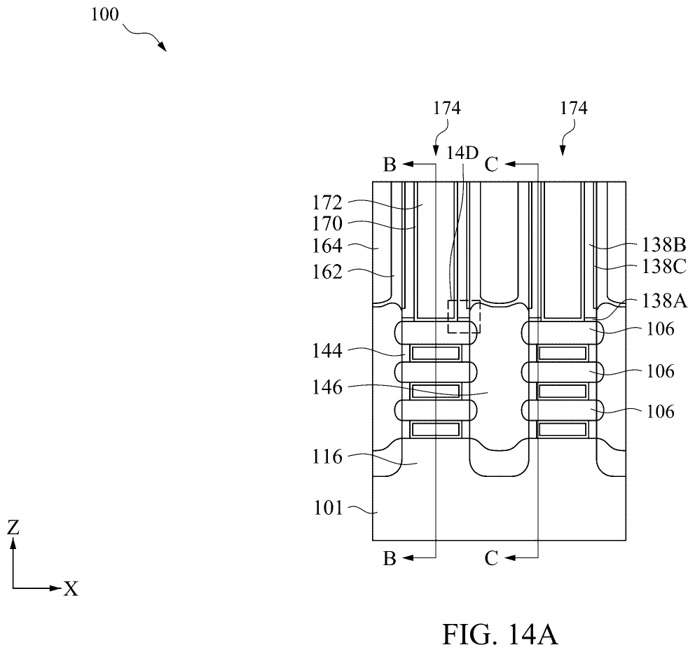

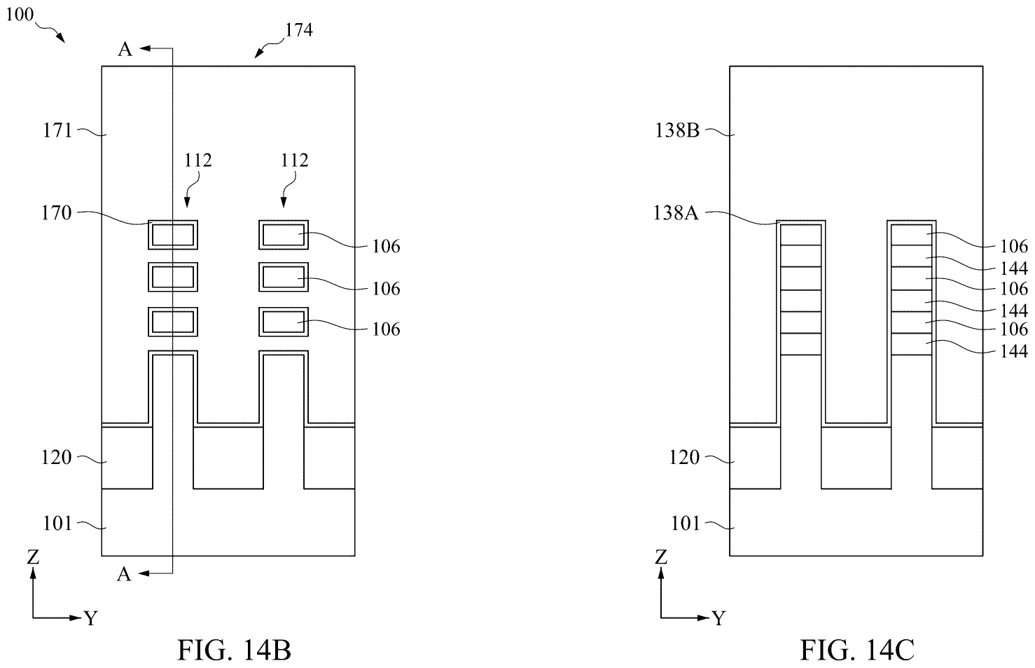

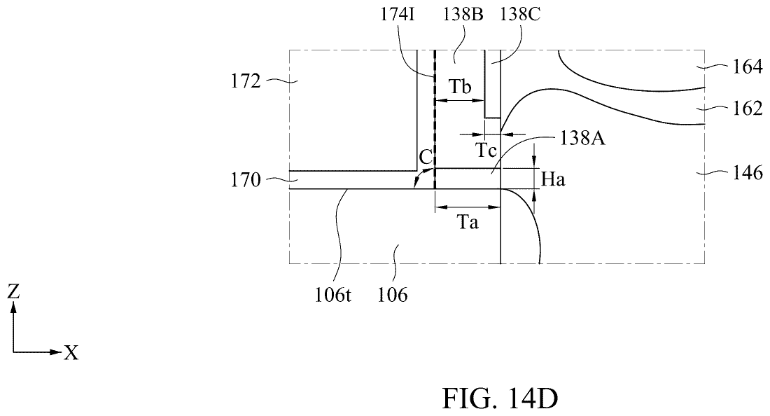

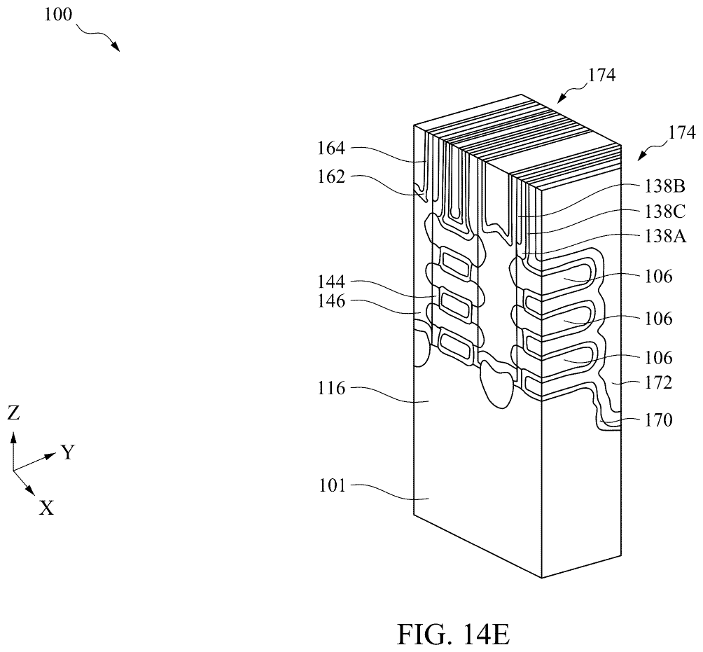

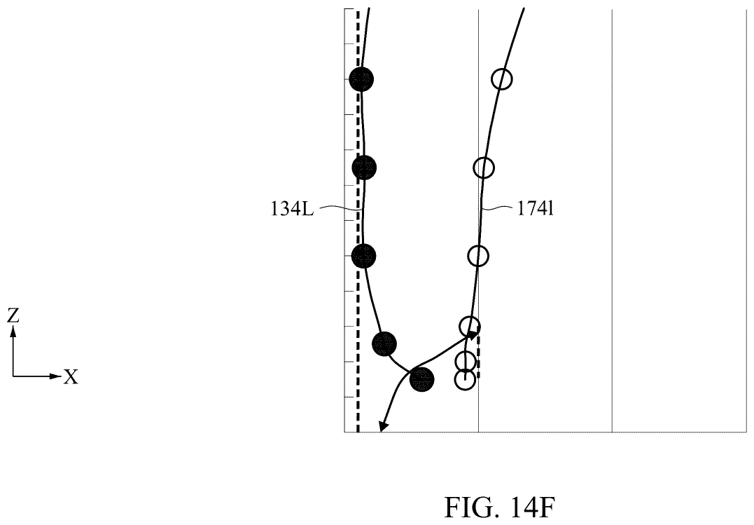

In operation 224, replacement gate structures 174 are formed, as shown in FIGS. 13A-13B and 14A-14E. FIG. 13A is cross-sectional view of the semiconductor device structure 100. FIG. 13B is a partial enlarged view of the semiconductor device structure 100 in area 13B of FIG. 13A. FIG. 14A is cross-sectional view of the semiconductor device structure 100 along the A-A line in FIG. 14B. FIGS. 14B and 14C are schematic cross sectional views of the semiconductor device structure 100 along the B-B line and C-C line in FIG. 13A respectively. FIG. 14D is a partial enlarged view of the semiconductor device structure 100 in area 14D of FIG. 14A. FIG. 14E is a schematic perspective cross sectional view of the semiconductor device structure 100.

Prior to forming the replacement gate structures 174, the sacrificial gate structure 130 and the second semiconductor layers 108 are removed. The removal of the sacrificial gate structure 130 and the semiconductor layers 108 forms an opening between gate sidewall spacer stack 138 and between first semiconductor layers 106. The ILD layer 164 protects the S/D regions 146 during the removal processes. The sacrificial gate structure 130 can be removed using plasma dry etching and/or wet etching.

The sacrificial gate electrode layer 134 may be first removed by any suitable process, such as dry etch, wet etch, or a combination thereof, followed by the removal of the exposed portions of the first sacrificial layer 103, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 and sacrificial layer 103 but not the gate spacers 138, the ILD layer 164, and the CESL 162.

The corner portions 134t, shown in FIG. 8A, of the sacrificial gate electrode layer 134 are kept to obtain a wider contact area between the replacement gate structure 174 and the topmost channel, i.e. the topmost semiconductor layer 106. The bottom layer 138A, which is in contact with the sacrificial gate electrode layer 134, has a greater etch selectivity over the sacrificial gate electrode layer 134 than the first interior layer 138B. During removal of the sacrificial gate electrode layer 134, the bottom layer 138A protects the first interior layer 138B allowing substantially removal of the sacrificial gate electrode layer 134, as a result, the sacrificial gate electrode layer 134 may be substantially removed without affecting the first interior layer 138B.

In some embodiments, after removal of the sacrificial gate electrode layer 134 and the sacrificial layer 103, the bottom layer 138A, which has a relatively high k value, is then removed. After removal of the exposed bottom layer 138A, the first interior layer 138B and a cross section of the bottom layer 138A is exposed to the gate recess 168, as shown in FIG. 13B.

Portions of the second semiconductor layers 108 are then removed using a selective wet etching process. In cases where the second semiconductor layers 108 are made of SiGe and the first semiconductor layers 106 are made of Si, the chemistry used in the selective wet etching process removes the SiGe while not substantially affecting Si, the remaining dielectric materials of the sidewall spacer stack 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After removal of the semiconductor layers 108, a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174, as shown in FIGS. 14A-14E.

In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

As shown in FIGS. 14C and 14D, portions of the bottom layer 138A are located between the first interior layer 134B and the semiconductor layers 108 and between the first interior layer 134B and the inner pacers 144. In some embodiments, the thickness of the portion of the bottom layer 138A is in a range between about 0.5 nm to about 1.5 nm. As shown in FIG. 14D, the gate dielectric layer 170 is in contact with the first interior layer 138B and a cross section of the bottom layer 138A.

The remaining gate sidewall spacer stack 138 functions as a gate sidewall spacer. In some embodiments, the gate sidewall spacer includes three layers of material, the bottom layer 138A, the bottom layer 138A, the first interior layer 138B and the second interior layer 138C. The first interior layer 138B faces the gate structure 174 and is in contact with the gate dielectric layer 170. The second interior layer 138C faces the source/drain regions 144 and is in contact with the CESL 162, and possible with a portion of source/drain region 144. The first interior layer 138B is disposed between the bottom layer 138A and the second interior 138C. The bottom layer 138A has a thickness Ta along the x-direction and a height Ha along the z-direction. In some embodiments, the height Ha is in a range between about 1 nm and about 1.5 nm. The thickness Ta is in a range between about 1 nm and about 4 nm. The first interior layer 138B has a thickness Tb along the x-direction. In some embodiments, the thickness Tb is in a range between about 0.5 nm and about 2 nm. The second interior layer 138C has a thickness Tc along the x-direction. In some embodiments, the thickness Tc is in a range between about 0.5 nm and about 2 nm.

As discussed above, because the corner portion 134t, the gate structure 174 has a substantially vertical sidewall over a top surface 106t of the topmost semiconductor layer 106. As shown in FIG. 14D, a profile 174l of the gate structure 174 form an angle C with the top surface 106t of the topmost semiconductor layer 106. In some embodiments, the angle C is in arrange between about 95 degrees to about 105 degrees. FIG. 14F includes an exemplary profile 134l of the sacrificial gate layer 134 and a gate profile 174l of the replacement gate structure 174. As shown in FIG. 14F, the extra footing in the profile 134l of the sacrificial gate layer 134 improves profile of the replacement gate structure 174.

Even though GAA devices are described above, embodiments may be used in any suitable devices, such as FinFET structures.

Embodiments of the present disclosure provide a semiconductor device structure 100 including a gate space sidewall spacer with a substantially vertical sidewall profile over the topmost channel layer. The vertical sidewall profile increases contact area between the gate electrode and the channel layer, therefore, reducing resistance and improving DC performance.

Some embodiments of the present provide a semiconductor device structure. The semiconductor device structure comprises a fin structure, a gate structure formed over the fin structure; a source/drain region in contact with the fin structure; a contact etch stop layer (CESL) disposed on the source/drain region; and a gate sidewall spacer disposed on a sidewall of the gate structure, wherein the gate sidewall spacer comprises: a first dielectric layer in contact with the fin structure; a second dielectric layer in contact with the gate structure layer; and a third dielectric layer in contact with the CESL, wherein the second dielectric layer is disposed between the first dielectric layer and third dielectric layer.

Some embodiments of the present disclosure provide a semiconductor device structure. The semiconductor device structure comprises a source/drain region disposed over a substrate; a fin structure in contact with the source/drain region; a gate structure disposed on the fin structure; a bottom dielectric layer disposed on an end portion of the fin structure, wherein the bottom layer is in contact with the gate structure and the fin structure; and a gate sidewall spacer disposed a sidewall of the gate structure and on the bottom dielectric layer.

Some embodiments of the present disclosure provide a method for forming a semiconductor device structure. The method comprises forming a fin structure from a substrate; depositing a first sacrificial layer around the fin structure; depositing a second sacrificial layer on the first sacrificial layer; etching second and first sacrificial layers to form a sacrificial gate structure; depositing a gate sidewall spacer stack, wherein the gate sidewall spacer stack comprises a bottom layer, a first interior layer, a second interior layer, and a top layer, the bottom layer has a first k value, the first interior layer has a second k value, and the first k value is greater than the second k value; recess etching a portion of the fin structure; forming a source/drain region from the exposed fin structure; and removing the second sacrificial layer and the first sacrificial layer; depositing a gate dielectric layer on the fin structure; and depositing a gate electrode layer on the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a fin structure;
a gate structure formed over the fin structure;
a source/drain region in contact with the fin structure;
a contact etch stop layer (CESL) disposed on the source/drain region; and
a gate sidewall spacer disposed on a sidewall of the gate structure, wherein the gate sidewall spacer comprises:
a first dielectric layer in contact with the fin structure;
a second dielectric layer in contact with the gate structure layer; and
a third dielectric layer in contact with the CESL, wherein the second dielectric layer is disposed between the first dielectric layer and third dielectric layer.

2. The semiconductor device structure of claim 1, wherein the first dielectric layer has a higher k-value than the second dielectric layer and the third dielectric layer.

3. The semiconductor device structure of claim 1, wherein the first dielectric layer is in contact with the gate structure and the source/drain region.

4. The semiconductor device structure of claim 3, wherein the second dielectric layer is in contact with the gate structure and the source/drain region.

5. The semiconductor device structure of claim 1, wherein the fin structure comprises two or more semiconductor channel layers, one or more inner spacers disposed between the two or more semiconductor layers, and the first dielectric layer is in contact with the two or more semiconductor layers and one or more inner spacers.

6. The semiconductor device structure of claim 5, wherein the dielectric layer has a thickness in a range between 1 nm and 1.5 nm.

7. The semiconductor device structure of claim 1, wherein a sidewall of the gate structure is in contact with the first dielectric layer and the second dielectric layer, the sidewall for an angle relative to a top surface of the fin structure, and the angle ranges from about 95 degrees to about 105 degrees.

8. A semiconductor device structure, comprising:
a source/drain region disposed over a substrate;
a fin structure in contact with the source/drain region;
a gate structure disposed on the fin structure;
a bottom dielectric layer disposed on an end portion of the fin structure, wherein the bottom layer is in contact with the gate structure and the fin structure; and
a gate sidewall spacer disposed a sidewall of the gate structure and on the bottom dielectric layer.

9. The semiconductor device structure of claim 8, wherein the sidewall of the gate structure and a top surface of the fin structure form an angle, and the angle ranges from about 95 degrees to about 105 degrees.

10. The semiconductor device structure of claim 9, wherein the bottom dielectric layer has a first k value, the gate sidewall spacer has a second k value, and the first k value is greater than the second k value.

11. The semiconductor device structure of claim 10, wherein the gate sidewall spacer comprises:
a first sidewall layer facing the gate structure; and
a second sidewall layer facing the source/drain region.

12. The semiconductor device structure of claim 11, wherein the first sidewall layer is disposed between the bottom dielectric layer and the second sidewall layer.

13. A method for forming a semiconductor device structure, comprising:
forming a fin structure from a substrate;
depositing a first sacrificial layer around the fin structure;
depositing a second sacrificial layer on the first sacrificial layer;
etching second and first sacrificial layers to form a sacrificial gate structure;
depositing a gate sidewall spacer stack, wherein the gate sidewall spacer stack comprises a bottom layer, a first interior layer, a second interior layer, and a top layer, the bottom layer has a first k value, the first interior layer has a second k value, and the first k value is greater than the second k value;
recess etching a portion of the fin structure;
forming a source/drain region from the exposed fin structure; and
removing the second sacrificial layer and the first sacrificial layer;
depositing a gate dielectric layer on the fin structure; and
depositing a gate electrode layer on the gate dielectric layer.

14. The method of claim 13, further comprising removing a portion of the bottom layer to expose the first interior layer, wherein the gate dielectric layer is deposited on the first interior layer.

15. The method of claim 14, wherein recess etching a portion of the fin structure comprises removing the top layer.

16. The method of claim 15, further comprising depositing a CESL on the source/drain region and the second interior layer.

17. The method of claim 13, wherein each the second sacrificial layer comprising:
performing a first etching process to form a sacrificial gate electrode layer, wherein a byproduct layer is formed on the sacrificial gate electrode layer, and the sacrificial gate electrode layer and the byproduct layer each includes one or more corner portions;
performing a second etching process to remove the one or more corner portions of the byproduct layer and to expose the one or more corner portions of the sacrificial gate electrode layer; and
performing a third etching process to remove at least one of the one or more corner portions of the sacrificial gate electrode layer.

18. The method of claim 17, wherein the sacrificial gate electrode layer includes a corner portion on a top surface of the fin structure.

19. The method of claim 17, wherein the corner portion extends along the fin structure for a distance between about 1 nm and about 2 nm.

20. The method of claim 13, wherein depositing the gate sidewall spacer stack comprises:
depositing the bottom layer from a process gas comprising a silicon source, a nitrogen source, a carbon source, and an oxygen source; and
ceasing a flow rate of the nitrogen source to form the first interior layer.
